(19) United States
(12) Patent Application Publication
(10) Pub. No.: US 2016/0079222 A1
(43) Pub. Date: Mar. 17, 2016

(54) SEMICONDUCTOR DEVICE HAVING TERMINALS FORMED ON A CHIP PACKAGE INCLUDING A PLURALITY OF SEMICONDUCTOR CHIPS AND MANUFACTURING METHOD THEREOF

(71) Applicant: KABUSHIKI KAISHA TOSHIBA, Tokyo (JP)

(72) Inventor: Takao SATO, Yokkaichi Mie (JP)

(21) Appl. No.: 14/842,630

(22) Filed: Sep. 1, 2015

(30) Foreign Application Priority Data
Sep. 16, 2014 (JP) 2014-188173

(51) Int. Cl. H01L 25/18; H01L 21/56; H01L 25/00; H01L 23/00; H01L 23/31; H01L 25/065

(52) U.S. Cl. CPC H01L 25/18; H01L 23/3114; H01L 25/0657; H01L 23/3142; H01L 25/50; H01L 24/11; H01L 24/17; H01L 21/56; H01L 2225/06513; H01L 2224/16145; H01L 2224/13016; H01L 2924/1434; H01L 2924/14

(57) ABSTRACT

A semiconductor device includes a chip package including plurality of stacked semiconductor chips, a sealing layer covering at least an upper surface of the chip package, a plurality of first conductive elements disposed on the chip package and exposed on an upper surface of the sealing layer, and a plurality of second conductive elements, each being disposed on one of the exposed surfaces of the first conductive elements.

### CROSS-REFERENCE TO RELATED APPLICATION

This application is based upon and claims the benefit of priority from Japanese Patent Application No. 2014-188173, filed Sep. 16, 2014, the entire contents of which are incorporated herein by reference.

### FIELD

Embodiments described herein relate generally to a semiconductor device, in particular, a semiconductor device having terminal formed on a chip package including a plurality of semiconductor chips, and a manufacturing method thereof.

### BACKGROUND

A semiconductor device, including a NAND-type flash memory, is demanded to have a smaller size and operate faster. A semiconductor device of one type, to meet these demands includes a chip package of plurality of stacked semiconductor chips, which forms a three-dimensional packaging structure. According to such a semiconductor device, lengths of wires between adjacent semiconductor chips can be reduced, and the semiconductor chips can be formed in a packed manner. Further, an operation frequency of the semiconductor device can be increased. The three-dimensional packaging structure includes a stack structure using, for example, a through silicon via (TSV) method.

To manufacture a semiconductor device with the three-dimensional packaging structure, typically, a plurality of semiconductor chips is first stacked on a supporting substrate such as a lead frame and thereby a chip-stacked structure is formed. Then, a plurality of conductive elements (bump), such as solder balls, is formed on the chip-stacked structure, and a space between semiconductor chips is sealed with an underfill resin. After that, the chip stacked structure is reversed, and the chip stacked structure is bonded to a wiring substrate so that the conductive elements are located therebetween. Furthermore, the chip stacked body is sealed with a sealing resin, an external connection terminal is formed on the wiring substrate, and thereafter the wiring substrate is singulated through dicing.

The chip package having the three-dimensional packaging structure tends to be warped, because an internal stress may remain in the structure during stacking the chips. If the chip package is warped, some of the conductive elements thereon may not be electrically connected to the wiring substrate, which is not warped. A semiconductor device having such a chip package may not operate reliably.

### DESCRIPTION OF THE DRAWINGS

FIGS. 1A and 1B illustrate a semiconductor device according to a first embodiment.

FIG. 2 is a flowchart illustrating a manufacturing method of the semiconductor device.

FIGS. 3-9B illustrates steps to manufacture the semiconductor device illustrated in FIG. 1.

FIGS. 10A and 10B illustrate a semiconductor device according to a second embodiment.

FIG. 11 is a flowchart illustrating another manufacturing method of the semiconductor device according to the second embodiment.

FIGS. 12-17 illustrate steps to manufacture the semiconductor device according to the second embodiment.

### DETAILED DESCRIPTION

An embodiment provides a semiconductor device that more reliably operates.

According to an embodiment, a semiconductor device includes a chip package including plurality of stacked semiconductor chips, a sealing layer covering at least an upper surface of the chip package, a plurality of first conductive elements disposed on the chip package and exposed on an upper surface of the sealing layer, and a plurality of second conductive elements, each being disposed on one of the exposed surfaces of the first conductive elements.

Hereinafter, embodiments will be described with reference to the drawings. In addition, the drawings are schematic, for example, there is a case where a relationship between a thickness and a planar dimension, ratio of the thickness of each layer, or the like may be different from actual one. In addition, in each embodiment, the same reference numerals and symbols are attached to substantially the same configuration elements, and description thereof will be omitted.

### First Embodiment

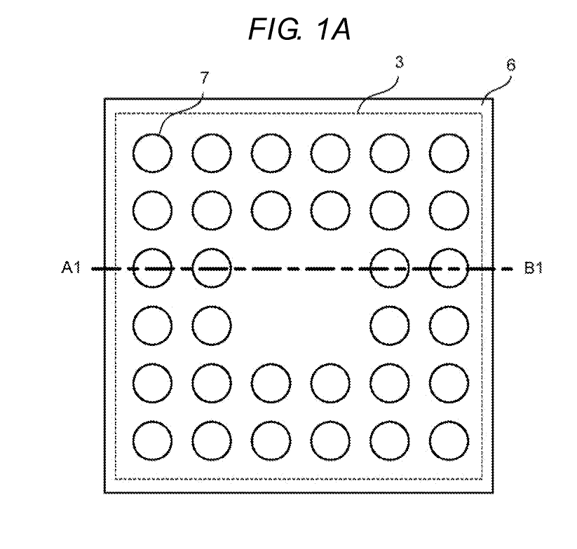

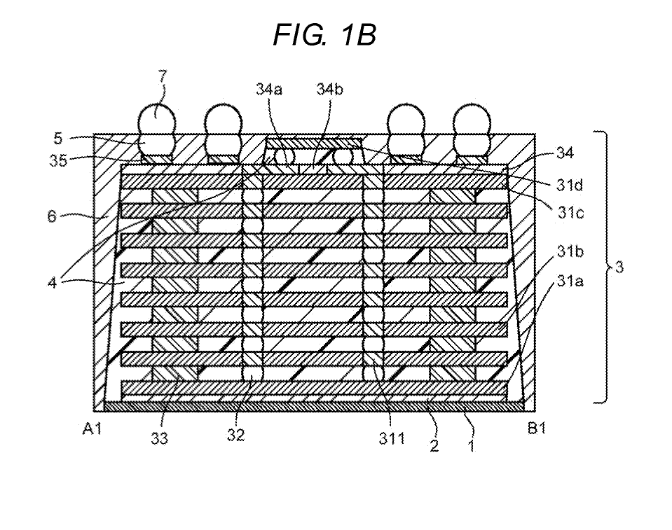

FIGS. 1A and 1B illustrate a configuration example of a semiconductor device. FIG. 1A is a top view of the semiconductor device, and FIG. 1B is a cross-sectional view of the semiconductor device cut along an A1-B1 line in FIG. 1A. The semiconductor device illustrated in FIGS. 1A and 1B is a fan-in type semiconductor device, and includes a supporting substrate 1, an adhesive layer 2, a chip-stacked structure 3 having a plurality of stacked semiconductor chips, a sealing resin layer 4, a bump 5, a sealing resin layer 6, and a bump 7. In FIG. 1, the supporting substrate 1 is positioned on a lower side of the semiconductor device and the bump 7 positioned on an upper side thereof, as an example. In the present embodiment, a vertical direction of the semiconductor device may be reversed. In addition, the number of elements of the bump 5 and the bump 7 are not limited to the number illustrated in FIG. 1

The supporting substrate 1 is a substrate on which the chip-stacked structure 3 is mounted. The supporting substrate 1 is formed of, for example, a metal material, a semiconductor material such as silicon, a resin material, a ceramic, or the like. As the supporting substrate 1, for example, a lead frame may be used. For the lead frame, an iron alloy, such as 42 alloy, and nickel may be used. In addition, the supporting substrate 1 may not be necessarily provided.

The adhesive layer 2 is provided on the supporting substrate 1. The adhesive layer 2 has a function of fixing the supporting substrate 1 to the chip-stacked structure 3. As the adhesive layer 2, a resin film such as polyimide may be used.

The chip-stacked structure 3 is provided on the supporting substrate 1, and the adhesive layer 2 is disposed therebetween. The chip-stacked structure 3 includes a semiconductor chip 31a, a semiconductor chip 31b, a semiconductor chip 31c, and a semiconductor chip 31d that are stacked above the supporting substrate 1. In addition, a type of the semiconductor chips is not limited to the semiconductor chips 31a-31d.

The semiconductor chip 31a is provided on the adhesive layer 2. For example, the semiconductor chip 31a includes a connection pad on its upper surface. In addition a via electrode, such as a TSV, that penetrates the semiconductor chip 31a may be provided in the semiconductor chip 31a.

One or more of the semiconductor chips 31b are disposed above the semiconductor chip 31a. The number of the stacked semiconductor chips 31b is not limited to the number illustrated in FIG. 1B. The semiconductor chip 31b at an undermost position is stacked on the semiconductor chip 31a, and a bump 32 and an adhesive layer 33 are disposed therebetween. The semiconductor chip 31b is electrically connected the semiconductor chip 31a through the bump 32. In addition, between adjacent semiconductor chips 31b, the bumps 32 and the adhesive layers 33 are disposed.

The adhesive layer 33 functions as a spacer for maintaining a gap between the semiconductor chip 31a and the semiconductor chip 31c. As the adhesive layer 33, for example, a thermosetting resin or the like may be used. In addition, spaces between the semiconductor chips 31a, 31b, and 31c may be sealed using an insulating adhesive material such as a non-conductive film (NCF), instead of the adhesive layer 33. The insulating adhesive material such as an NCF has both sealing and adhesive functions, and thus an underfill resin is not required.

The plurality of semiconductor chips 31b each includes a via electrode 311, such as a TSV, that penetrates the semiconductor chips 31b, and are electrically connected to each other through the bump 32. For example, the semiconductor chip 31b includes connection pads on an upper surface and a lower surface thereof. The bump 32 is provided between the connection pads on one surface of the semiconductor chip 31a and the connection pads on the other surface of the semiconductor chip 31b, and between the connection pads of the plurality of semiconductor chips 31b. For the via electrode 311, for example, the simple substance, such as nickel, copper, silver, or gold may be used or alloy thereof may be used. In this way, by using the chip-stacked structure 3 connected through the TSV, a surface area of the chip package may be reduced, and the number of connection terminals may be increased, and thus it is possible to decrease connection failure or the like.

The semiconductor chip 31c also includes a via electrode 311, such as a TSV, that penetrates the semiconductor chip 31c. The semiconductor chip 31c is stacked on the semiconductor chip 31b, and the bump 32 and the adhesive layer 33 are disposed therebetween. The semiconductor chip 31c is electrically connected to the semiconductor chip 31b through the bump 32 and the via electrode 311. The semiconductor chip 31c includes a wiring layer 34 on its upper surface. The wiring layer 34 is a wiring layer (rewiring layer) that rearranges the wiring of the semiconductor chip 31a. The wiring layer 34 includes a plurality of connection wirings including a connection wiring 34a, and an insulating layer 34b. The connection wiring 34a is electrically connected to the via electrode 311 of the semiconductor chip 31c. A plurality of electrode pads 35 is provided on the wiring layer 34.

As the semiconductor chips 31a, 31b, and 31c, for example, memory chips or the like may be used. As the memory chip, a memory element such as a NAND type flash memory may be used. In addition, a circuit such as a decoder may be provided in the memory chip.

The semiconductor chip 31d is stacked on the wiring layer 34, and is electrically connected to the semiconductor chip 31c through the connection wiring 34a. As the connection wiring 34a and the electrode pad 35, a single layer or a stacked layer of, for example, copper, titanium, titanium nitride, chromium, nickel, gold, palladium or the like may be used.

As the semiconductor chip 31d, for example, an interface chip or a controller chip may be used. For example, if the semiconductor chips 31a, 31b, and 31c are all memory chips, the semiconductor chip 31d may serve as a controller chip, and writing and reading to and from the memory chips 31a, 31b, and 31c may be controlled by the semiconductor chip 31d. In addition, it is preferable that the semiconductor chip 31d be smaller than the semiconductor chips 31a-31c.

The sealing resin layer 4 is disposed between at least the semiconductor chips 31a, 31b, 31c, and 31d. At this time, the sealing resin layer 4 may be provided so as to cover side surfaces of the semiconductor chips 31a, 31b, 31c, and 31d. As the sealing resin layer 4, for example, an underfill resin or the like may be used.

The bump 5 is provided on the electrode pad 35 of the chip-stacked structure 3, and is electrically connected to the semiconductor chip 31c through the connection wirings other than the connection wiring 34a in the wiring layer 34.

The bump 5 may be formed of, for example, a tin-silver-based lead-free solder or a tin-silver-copper-based lead-free solder. As the bump 5, a single layer or a stacked layer of, for example, copper, titanium, titanium nitride, chromium, nickel, gold, palladium, or the like may be used. In FIG. 1, the bump 5 is a plurality of solder balls. In addition, the electrode pad 35 may be regarded as a portion of the bump 5.

The sealing resin layer 6 seals the chip-stacked structure 3. In addition, the sealing resin layer 6 may cover side surfaces of the supporting substrate 1. In addition, by exposing a surface of the supporting substrate 1 opposite to the surface on which the chip-stacked structure 3 is formed, heat dissipation may be increased. While not being limited to this, the surface of the supporting substrate 1 opposite to a surface on which the chip-stacked structure 3 is formed, may be covered with the sealing resin layer 6.

The sealing resin layer 6 includes at least an inorganic filler such as SiO₂. For example, it is possible to configure the sealing resin layer 6 using a mixture of an inorganic filler and an organic resin such as an epoxy resin. It is preferable that an amount of the contained inorganic filler be equal to or more than 80% and be equal to or less than 95%. The sealing resin layer 6 is suitable for increasing adhesion to the supporting substrate 1.

When the bump is formed on the chip-stacked structure and the chip-stacked structure is sealed by the sealing resin layer, warpage of the semiconductor chips is likely to occur. The semiconductor chip has a residual stress and the like therein produced when a semiconductor element or the like is formed. In addition, rigidity is decreased if being thinned. As a result, when the bump is formed on the chip-stacked structure, warpage is likely to be produced in a concave direction in such a manner that the side of the supporting substrate 1 becomes a convex shape. In the chip-stacked structure, the more semiconductor chips are stacked, the greater stress the semiconductor chips stacked on the lower semiconductor chip tend to include, and the warpage is likely to become significant. When the warpage is produced, heights of the bump increases toward a periphery from a center, and as a result the heights of the bump may become non-uniform.

In contrast to this, in the semiconductor device illustrated in FIG. 1, the bump 5 is provided on the chip stacked layer 3 and embedded in the sealing resin layer 6, and includes a flat surface (exposed surface) 51 exposed on an upper surface of the sealing resin layer 6. The flat surface 51 functions as a land of the bump 7. By providing the flat surface 51, a surface on which the bump 7 is formed may be flush with respect to an upper surface of the sealing resin layer 6. At this time, an area of the flat surface 51 of the plurality of bump 5 may become large as the bump 5 becomes close to the periphery.

The bump 7 is provided on the flat surface 51 of the layer 5. The bump 7 functions as an external connection terminal. In addition, a combination of the bump 5 and the bump 7 may be regarded as a bump. For the bump 7, for example, a tin-silver-based lead-free solder or a tin-silver-copper-based lead-free solder may be used. As the bump 7, a single layer or a stacked layer of, for example, copper, titanium, titanium nitride, chromium, nickel, gold, palladium, or the like may be used. In FIG. 1, the bump 7 is a solder ball, while not being limited to the solder ball.

As described above, the semiconductor device according to the present embodiment includes the sealing resin layer, the first bump having the flat surface along the upper surface of the sealing resin layer, and the second bump on the flat surface of the first bump. As a result, even when the warpage of the semiconductor chip is produced in the chip-stacked structure, it is possible to reduce variation of heights of the bumps. Thus, for example, when a semiconductor device is mounted on other substrate or the like, it is possible to decrease a connection failure or the like, and to maintain reliability of the semiconductor device.

In addition, the semiconductor device according to the present embodiment has a fan-in type structure in which the bump on the chip-stacked structure may be used as an external connection terminal. Thus, the semiconductor device may not be necessarily mounted on a separate wired substrate. Thus, it is possible to reduce a size of the semiconductor device.

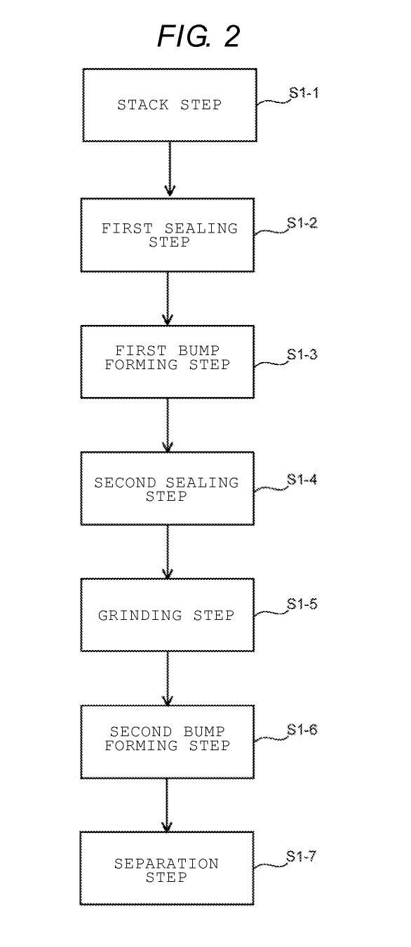

Next, a manufacturing method of the semiconductor device illustrated in FIG. 1 will be described with reference to FIG. 2. FIG. 2 is a flowchart illustrating a manufacturing method of the semiconductor device. The manufacturing method of the semiconductor device includes at least a stack step (S1-1) of forming the chip stacked body by stacking a plurality of semiconductor chips, a first sealing step (S1-2) of forming a first sealing resin layer that fills spaces between a plurality of semiconductor chips, a first bump forming step (S1-3) of forming a first bump on the chip stacked body, a second sealing step (S1-4) of forming a second sealing resin layer that covers the first bump and the chip stacked body, a grinding (removing) step (S1-5) of grinding (removing) a portion of the first bump and a portion of the sealing resin layer along a stack direction of the semiconductor chip until the first bump is exposed on the upper surface of the sealing resin layer, a second bump forming step (S1-6) of forming a second bump on the ground surface of the first bump, and a separation (dividing) step (S1-7) of separating (dividing) the supporting substrate according to the chip stacked body. Each step may be performed in a state of being fixed to, for example, a stage, a substrate, a tape, or the like. In addition, a sequence of each step may not be limited to the sequence illustrated in FIG. 2. In addition, a plurality of semiconductor devices may be formed through the same steps.

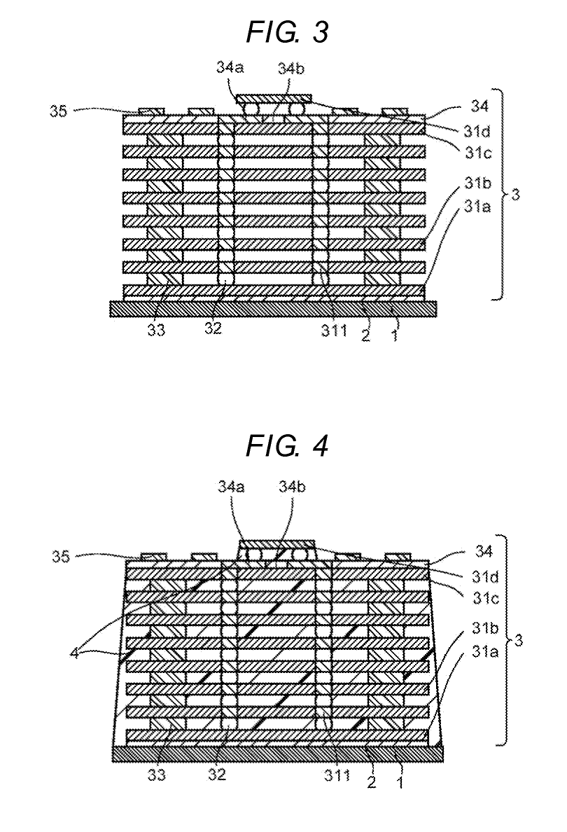

Furthermore, the above-described steps will be described with reference to FIG. 3 to FIG. 9. FIG. 3 to FIG. 9 illustrate steps of the manufacturing method of the semiconductor device. Here, as one example, a lead frame is used for the supporting substrate 1.

In the stack step (S1-1), as illustrated in FIG. 3, the semiconductor chips 31a, 31b, 31c, and 31d are stacked, whereby the chip-stacked structure 3 is formed. For example, the semiconductor chips 31a, 31b, 31c, and 31d may be stacked using a mounter or the like.

In the stack step (S1-1), the adhesive layer 2 is first formed on the semiconductor chip 31a in advance. Then, the semiconductor chip 31a is stacked on the supporting substrate 1 with the adhesive layer 2 disposed therebetween, and the adhesive layer 2 is cured by heating, so as to adhere to the semiconductor chip 31a. At this time, when a plurality of semiconductor devices is manufactured by the same steps, a collective substrate may be used as the supporting substrate 1.

Next, the plurality of semiconductor chips 31b, each having the bumps 32 and the adhesive layer 33 on a first surface thereof and the via electrodes 311, are stacked on the semiconductor chip 31a with the bumps 32 and the adhesive layer 33 disposed therebetween. At this time, the connection pads of the semiconductor chip 31a are bonded to the connection pads of the semiconductor chip 31b through the bumps 32 through, for example, heating. The bumps 32 and the adhesive layer 33 are formed on at least one of two semiconductor chips, and the other of the two is stacked thereon.

Next, the semiconductor chip 31c having the wiring layer 34 and the electrode pads 35 on a first surface thereof and the bumps 32 and the adhesive layer 33 on a second surface thereof, are stacked on the semiconductor chip 31b with the bumps 32 and the adhesive layer 33 disposed therebetween. At this time, the semiconductor chips 31a, 31b, and 31c are bonded together through the via electrode 311 and the bumps 32 using, for example, heating.

Next, the semiconductor chip 31d is stacked on the wiring layer 34. The semiconductor chip 31d is electrically connected to the connection wiring 34a, through, for example, the bump by reflow or the like under, for example, thermo-compression bonding or reflow with a reductant. Through the above-described steps, the chip-stacked structure 3 may be formed.

In the first sealing step (S1-2), as illustrated in FIG. 4, the sealing resin layers 4 are formed between the semiconductor chip 31a, 31b, 31c, and 31d, and on the side surfaces of the semiconductor chips 31a, 31b, 31c, and 31d. For example, underfill resin is filled between the semiconductor chips 31a, 31b, 31c, and 31d using a dispenser or the like, and thereby the sealing resin layer 4 maybe formed. In addition, a sealing step between the semiconductor chips 31a, 31b, and 31c may be performed separately from a sealing step between the semiconductor chip 31c and the semiconductor chip 31d. In addition, a groove may be formed in the supporting substrate 1 so as to surround the chip-stacked structure 3. As a result, when the plurality of semiconductor devices is manufactured through, for example, the same steps, it is possible to suppress that the underfill resin flows out to an area in which adjacent chip-stacked structure 3 is formed.

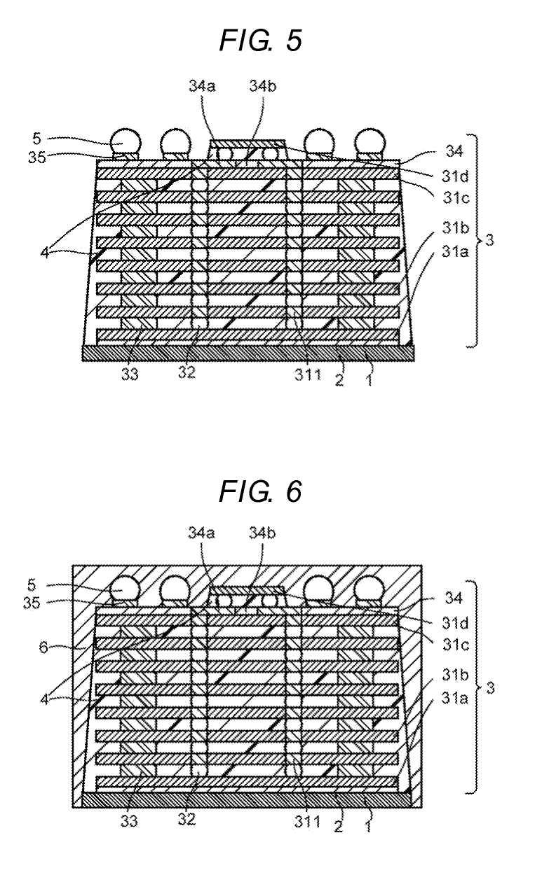

In the first bump forming step (S1-3), as illustrated in FIG. 5, the bump 5 is formed on the chip-stacked structure 3. For example, a plurality of solder balls is provided on the electrode pads 35 using a ball mounter or the like, whereby the bump 5 may be formed.

In the second sealing step (S1-4), as illustrated in FIG. 6, the sealing resin layer 6 which covers the chip-stacked structure 3 and the bump 5 are formed. A sealing rein for the sealing resin layer 6 is filled and cured so as to cover the chip-stacked structure 3 and the bump 5 using, for example, a transfer molding method, a compression molding method, injection molding method or the like, and thereby the sealing resin layer 6 may be formed. When a plurality of semiconductor devices is manufactured through the same steps, it is preferable that the sealing resin layer 6 be formed so as to be formed between adjacent chip-stacked structures 3.

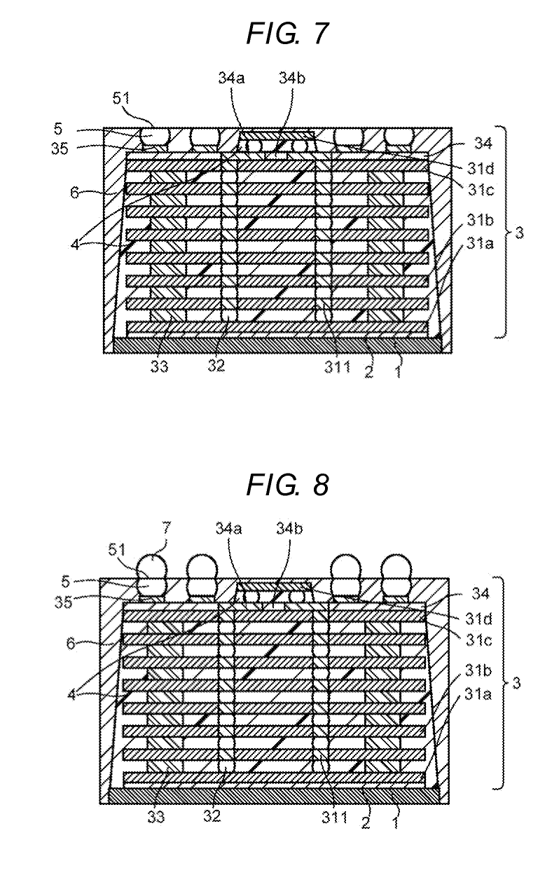

In the grinding step (S1-5), as illustrated in FIG. 7, a part of the bump 5 and a portion of the sealing resin layer are removed along a stacked layer direction of the semiconductor chips by grinding until the bump 5 is exposed on an upper surface of the sealing resin layer 6. As a result, the flat surface 51 is formed on the bump 5 along the upper surface of the sealing resin layer 6. The part of the bump 5 and the portion of the sealing resin layer 6 are ground using, for example, a grindstone or the like, whereby the flat surface 51 may be formed. While not being limited to this, by performing blasting processing or chemical mechanical polishing (CMP) processing, the part of the bump 5 and the portion of the sealing resin layer 6 may be ground.

In the second bump forming step (S1-6), as illustrated in FIG. 8, the bump 7 is formed on the flat surface 51 that is the exposed surface of the bump 5. For example, after flux is coated on the flat surface 51 of the bump 5, a solder ball is mounted on the flat surface 51 of the bump 5 using a ball mounter or the like, the solder ball is melted in a reflow oven, and the electrode pad 35 is bonded. Thereafter, the flux is removed by solvents or pure water cleaning, whereby the bump 7 may be formed.

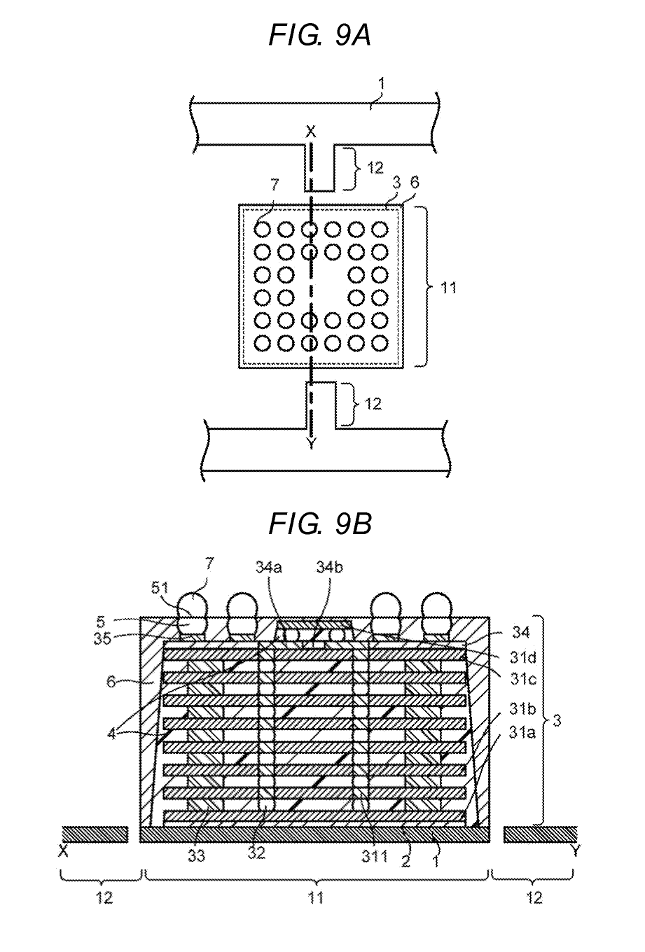

In the separation step (S1-7), as illustrated in FIGS. 9A and 9B, a portion of the supporting substrate 1 including a chip mounting portion is separated according to the chip-stacked structure 3. FIG. 9A is a planar view after the supporting substrate 1 that is a lead frame on which the chip-stacked structure 3 is provided is separated, and FIG. 9B is a cross-sectional view of an X-Y line in FIG. 9A that is in a direction along a hanging pin portion different from a cross-sectional direction illustrated in FIG. 3 to FIG. 8.

The supporting substrate 1 illustrated in FIG. 9 includes a chip mounting portion 11, and a hanging pin portion 12 that supports the chip mounting portion 11. The chip-stacked structure 3 is formed on the chip mounting portion 11 that is provided in the supporting substrate 1. In the separation step (S1-7), the hanging pin portion 12 is cut using, for example, a dicing blade, whereby a portion of the supporting substrate 1 including the chip mounting portion 11 may be separated according to the chip-sacked structure 3. As described above, a semiconductor device is manufactured. In addition, when a plurality of semiconductor devices are formed, a portion of the supporting substrate 1 including the chip mounting portion 11 for each chip-stacked structure 3 is separated. When a semiconductor device is manufactured using a collective substrate, a portion of the collective substrate is separated, whereby the separated portion of the collective substrate becomes the supporting substrate 1.

As described above, in the manufacturing method of a semiconductor device according to the present embodiment, the first bump is formed on the chip stacked body, and thereafter the sealing resin layer that covers the first bump and the chip stacked body are formed. After that, a portion of the first bump and a portion of the sealing resin layer are removed along the direction in which the semiconductor chips are stacked. As a result, the flat surface may be formed in the first bump along the upper surface of the sealing resin layer. Furthermore, by forming the second bump on the flat surface of the first bump, it is possible to decrease variation of the height of the bump, even when warpage of the semiconductor chip in the chip stacked body occurs.

### Second Embodiment

In the present embodiment, a semiconductor device having a structure of the first bump different from that of the semiconductor device according to the first embodiment will be described. In addition, with regard to the portions that are the same as those of the semiconductor device according to the first embodiment, the description of the first embodiment may be appropriately employed.

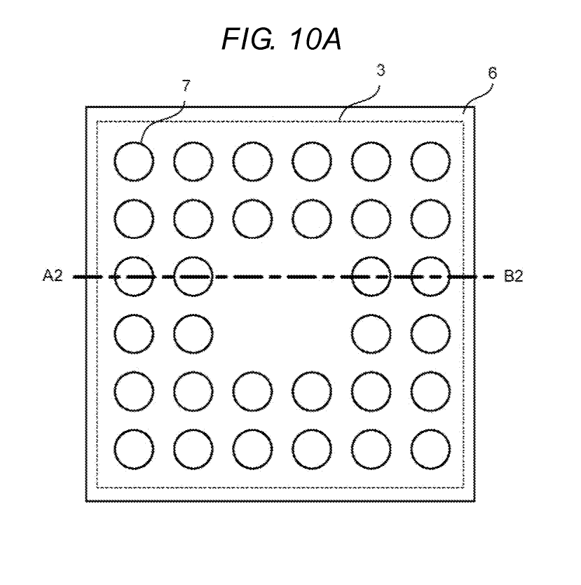

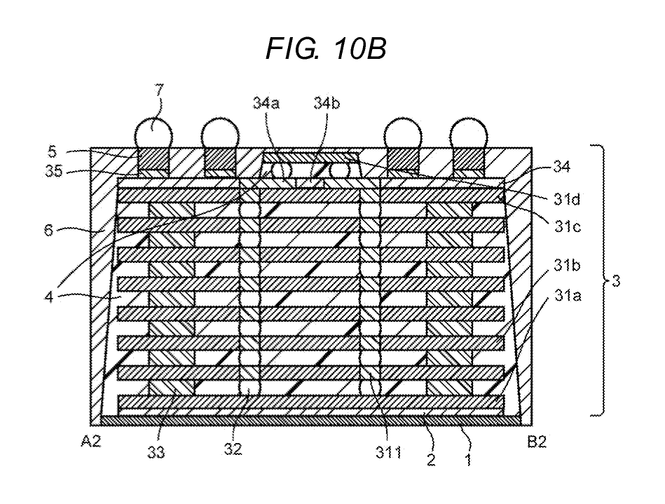

FIGS. 10A and 10B illustrate a semiconductor device according to the second embodiment. FIG. 10A is a top view, and FIG. 10B is a cross-sectional view cut along an A2-B2 line in FIG. 10A. The semiconductor device illustrated in FIGS. 10A and 10B is a fan-in type semiconductor device that is the same as the semiconductor device illustrated in FIG. 1, and includes the supporting substrate 1, the adhesive layer 2, the chip-stacked structure 3 having a plurality of stacked semiconductor chips, the sealing resin layer 4 that seals a space between the semiconductor chips, the bump 5 that is provided on the chip-stacked structure 3, the sealing resin layer 6 that seals the chip-stacked structure 3, and the bump 7 that is provided on the bump 5. In addition, in FIGS. 10A and 10B, as an example, the supporting substrate 1 is illustrated so as to be positioned on a lower side, and the bump is illustrated so as to be positioned on an upper side, but a vertical direction of the semiconductor device may be reversed. In addition, the number of the bump 5 and the bump 7 is not limited to the number illustrated in FIGS. 10A and 10B. With regard to the supporting substrate 1, the adhesive layer 2, the chip-stacked structure 3, the sealing resin layer 4, the sealing resin layer 6, and the bump 7, the description of the first embodiment is appropriately employed, and hereinafter, the bump 5 will be described.

The bump 5 is provided so as to be embedded in the sealing resin layer 6, and includes the flat surface 51 that is exposed from the sealing resin layer 6 along an upper surface of the sealing resin layer 6. The bump 5 is provided on the electrode pad 35 of the chip-stacked structure 3, and is electrically connected to the semiconductor chip 31c through a wiring other than the connection wiring 34a of the wiring layer 34, for example.

The bump 5 may use, for example, a tin-silver-based lead-free solder or a tin-silver-copper-based lead-free solder. As the bump 5, a single layer or a stacked layer of, for example, copper, titanium, titanium nitride, chromium, nickel, gold, palladium, or the like may be used. In FIGS. 10A and 10B, a case where the bump 5 is an embedded electrode is illustrated. In addition, the electrode pad 35 may be regarded as a portion of the bump 5.

The semiconductor device according to the present embodiment is slightly different from the semiconductor device according to the first embodiment in that the first bump is configured with an embedded electrode. By configuring the first bump with the embedded electrode, for example, diameters of the plural elements of the first bump may be equal to each other, and thus it is possible to decrease a bonding failure to the second bump. Thus, it is possible to suppress a decrease of reliability.

In addition, the semiconductor device according to the present embodiment has a fan-in type structure in which the second bump on the chip stacked body may be used as an external connection terminal, in the same manner as the first embodiment. Thus, the semiconductor device may not be necessarily mounted on a separate wiring substrate. Thus, it is possible to reduce a size of a semiconductor device.

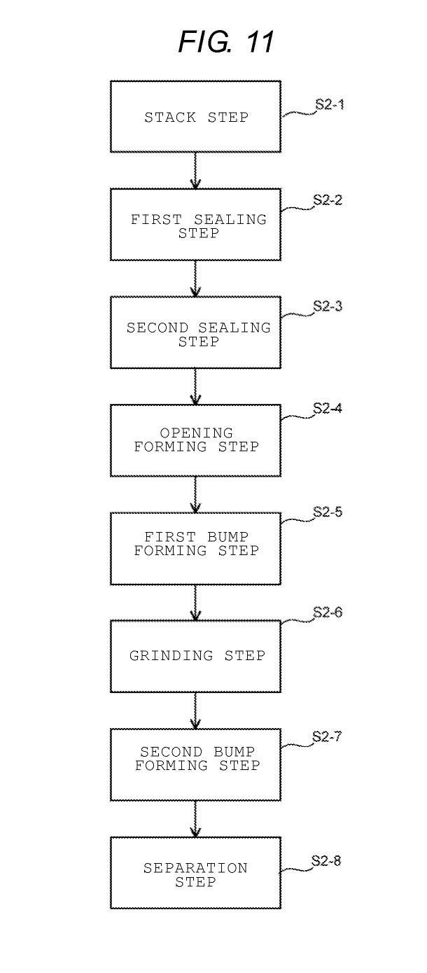

Next, the manufacturing method of the semiconductor illustrated in FIGS. 10A and 10B will be described with reference to FIG. 11. FIG. 11 is a flowchart illustrating a manufacturing method example of a semiconductor device. The manufacturing method example of the semiconductor device includes at least a stack step (S2-1) of forming the chip stacked body by stacking a plurality of semiconductor chips, a first sealing step (S2-2) of forming a first sealing resin layer that seals spaces between a plurality of semiconductor chips, a second sealing step (S2-3) of forming a second sealing resin layer that covers the chip stacked body, an opening forming step (S2-4) of forming an opening in the second sealing resin layer so as to expose a portion of the chip stacked body, a first bump forming step (S2-5) of forming a first bump by providing a conductive layer so as to embed the opening, a grinding step (S2-6) of grinding a part of the first bump and a portion of the sealing resin layer along a stack direction of the semiconductor chip until the first bump is exposed on the upper surface of the sealing resin layer, a second bump forming step (S2-7) of forming a second bump on the ground surface of the first bump, and a separation step (S2-8) of separating the supporting substrate according to the chip stacked body. In addition, a sequence of each step may not be limited to the sequence illustrated in FIG. 11. In addition, a plurality of semiconductor devices maybe formed by the same step.

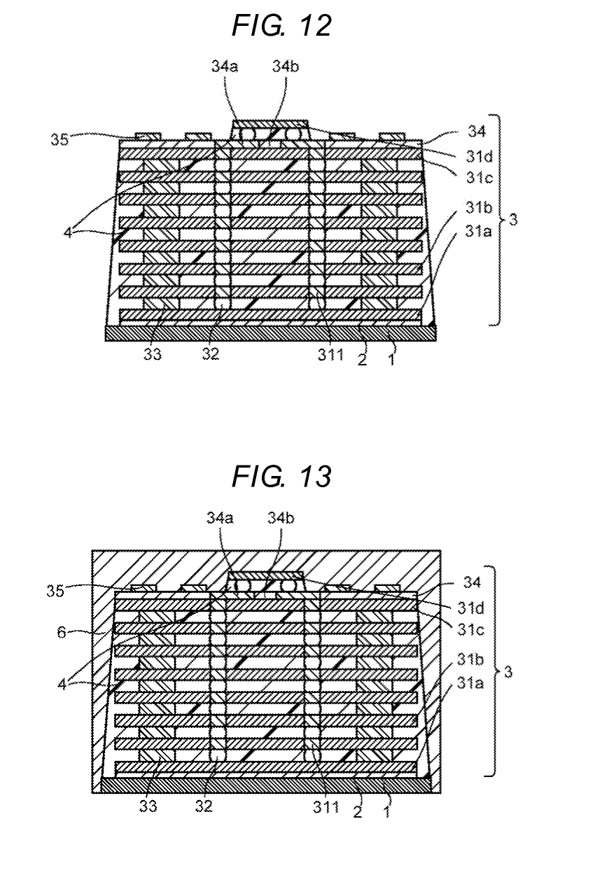

Furthermore, the above-described steps will be described with reference to FIG. 12 to FIG. 17. FIG. 12 to FIG. 17 illustrate a manufacturing method of the semiconductor device according to the second embodiment. Here, as one example, a case where a lead frame is used for the supporting substrate 1 will be described.

As illustrated in FIG. 12, in the stack step (S2-1), the chip-stacked structure 3 is formed in the same manner as the stack step (S1-1), and in the first sealing step (S2-2), the sealing resin layer 4 is formed in the same manner as the first sealing step (S1-2). With regard to the other descriptions, the descriptions on the stack step (S1-1) and the first sealing step (S1-2) may be appropriately employed, and thus the other descriptions will be omitted.

In the second sealing step (S2-3), as illustrated in FIG. 13, the sealing resin layer 6 that covers the chip-stacked structure 3 is formed. With regard to the other descriptions, the descriptions on the second sealing step (S1-4) may be appropriately employed, and thus the other descriptions will be omitted.

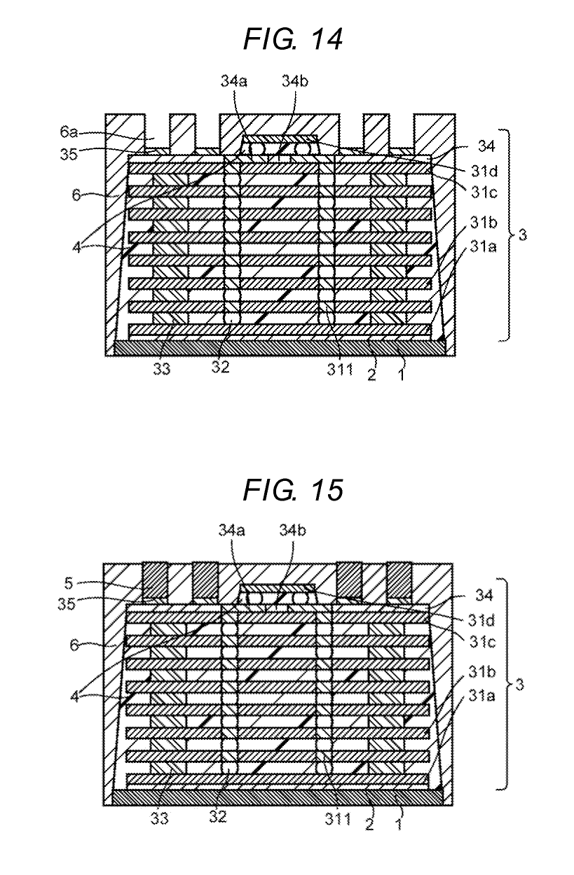

In the opening forming step (S2-4), as illustrated in FIG. 14, an opening 6a is formed in the sealing resin layer 6 so as to expose a portion (herein, at least a portion of electrode pad 35) of the chip-stacked structure 3. For example, by radiating laser light into the sealing resin layer 6, the opening 6a may be formed. While not being limited to this, the opening 6a may be formed using, for example, a photolithography technique.

In the first bump forming step (S2-5), as illustrated in FIG. 15, the bump 5 is formed on the chip-stacked structure 3. For example, the bump 5 may be formed by providing a conductive layer so as to embed the opening 6a using a metal conductive paste, a solder material, or the like that may be applied to the bump 5. In addition, a conductive layer may be formed so as to cover the sealing resin layer 6. In addition, if the bump 5 may be formed so as to embed the opening 6a, the bump 5 may be formed using other methods.

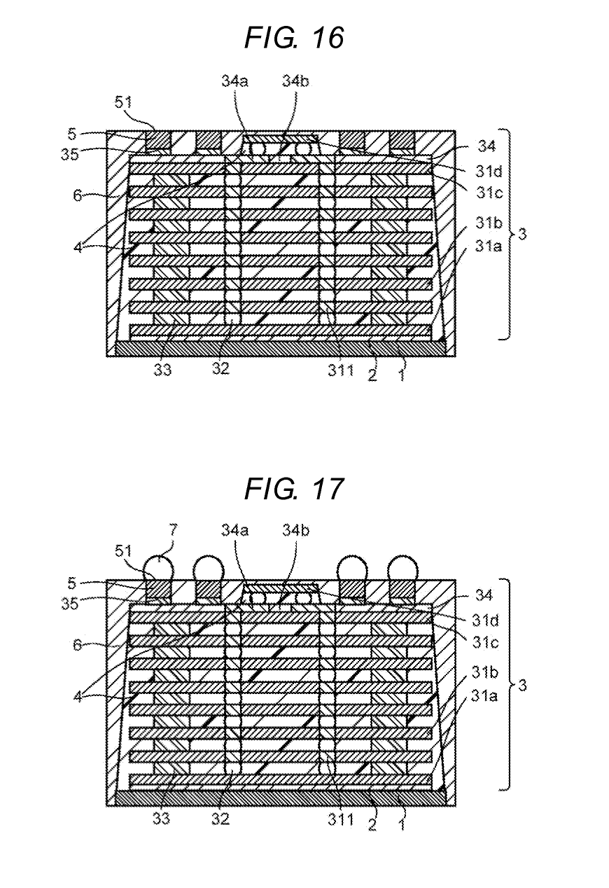

In the grinding step (S2-6), as illustrated in FIG. 16, a part of the bump 5 and a portion of the sealing resin layer are ground along a layer stacking direction of the semiconductor chips. As a result, the flat surface 51 is formed on the bump 5 along the upper surface of the sealing resin layer 6. With regard to the other descriptions, the descriptions on the grinding step (S1-5) maybe appropriately employed, and thus the other descriptions will be omitted.

In the second bump forming step (S2-7), as illustrated in FIG. 17, the bump 7 is formed on the flat surface 51 that is the ground surface of the bump 5. With regard to the other descriptions, the descriptions on the second bump forming step (S1-6) may be appropriately employed, and thus the other descriptions will be omitted.

In the separation step (S2-8), a portion of the supporting substrate 1 including a chip mounting portion is separated according to the chip-stacked structure 3, in the same manner as the separation step (S1-7). With regard to the other descriptions, the descriptions on the separation step (S1-7) may be appropriately employed, and thus the other descriptions will be omitted. As described above, the semiconductor device is manufactured.

As described above, in the manufacturing method of the semiconductor device according to the present embodiment, the sealing resin layer that covers the chip stacked body is formed, and thereafter, the opening is formed in the sealing resin layer so as to expose a portion of the chip stacked body. After that, the first bump is formed by providing the conductive layer so as to embed the opening, and thereafter, a portion of the first bump and a portion of the sealing resin layer are ground along a direction in which the semiconductor chips are stacked. As a result, it is possible to form the first bump with small diameter variation. In addition, it is possible to form the flat surface on the first bump along the upper surface of the sealing resin layer. Furthermore, the second bump is formed on the flat surface of the first bump, and thereby it is possible to reduce variation of the height of the bump, even when the warpage of the semiconductor chip in the chip stacked body occurs.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a chip package including plurality of stacked semiconductor chips;
a sealing layer covering at least an upper surface of the chip package;
a plurality of first conductive elements disposed on the chip package and exposed on an upper surface of the sealing layer; and
a plurality of second conductive elements, each being disposed on one of the exposed surfaces of the first conductive elements.

2. The semiconductor device according to claim 1, wherein
exposed surfaces of the first conductive elements and the upper surface of the sealing layer form a flat surface.

3. The semiconductor device according to claim 1, wherein
the first conductive elements are electrically connected to at least one of the semiconductor chips.

4. The semiconductor device according to claim 1, wherein
each of the first conductive elements is a solder ball having a flat upper surface.

5. The semiconductor device according to claim 1, wherein
each of the first conductive elements extends straight upward from the chip package.

6. The semiconductor device according to claim 1, wherein
each of the second conductive elements is a solder ball.

7. The semiconductor device according to claim 1, further comprising:
a substrate on which the chip package is formed.

8. The semiconductor device according to claim 6, wherein
the sealing layer covers side surfaces of the chip package and side surfaces of the substrate.

9. The semiconductor device according to claim 1, wherein
the semiconductor chips include a controller chip and a plurality of memory chips.

10. The semiconductor device according to claim 9, wherein
the controller chip is stacked at the top of the stacked semiconductor chips.

11. The semiconductor device according to claim 1, wherein
an exposed surface of first one of the first conductive elements is smaller than an exposed surface of second one of the first conductive elements that is located farther from a center of the chip package than the first one of the first conductive elements.

12. A method for manufacturing a semiconductor device, comprising:
forming a chip package including plurality of stacked semiconductor chips;
forming a plurality of first conductive elements on the chip package;
forming a sealing layer that covers at least an upper surface of the chip package;
removing an upper portion of the sealing layer and an upper portion of each first conductive elements, such that an upper surface of the sealing layer and upper surfaces of the first conductive elements exposed thereon form a flat surface; and
forming a plurality of second conductive elements, each on one of the exposed surfaces of the first conductive elements.

13. The method according to claim 12, wherein the chip package is formed on a portion of a substrate, the method further comprising:
separating the portion of the substrate on which, the chip package, the sealing layer, the first conductive elements, and the second conductive elements are formed, from the substrate.

14. The method according to claim 12, wherein each of the first conductive elements is a solder ball, and each of the second conductive elements is a solder ball.

15. The method according to claim 12, wherein
the semiconductor chips include a controller chip and a plurality of memory chips, and
the controller chip is stacked at the top of the stacked semiconductor chips.

16. The method according to claim 12, wherein
the sealing layer is formed so as to entirely cover the first conductive elements.

17. A method for manufacturing a semiconductor device, comprising:
forming a chip package including plurality of stacked semiconductor chips;
forming a sealing layer that covers at least an upper surface of the chip package;
forming a plurality of openings that penetrates the sealing layer;
forming a plurality of first conductive elements in the openings;
removing an upper portion of the sealing layer and an upper portion of each first conductive elements, such that an upper surface of the sealing layer and upper surfaces of the first conductive elements exposed thereon form a flat surface; and
forming a plurality of second conductive elements, each on one of the exposed surfaces of the first conductive elements.

18. The method according to claim 17, wherein the chip package is formed on a portion of a substrate, the method further comprising:
separating the portion of the substrate on which, the chip package, the sealing layer, the first conductive elements, and the second conductive elements are formed, from the substrate.

19. The method according to claim 17, wherein each of the first conductive elements extends straight upward from the chip package, and each of the second conductive elements is a solder ball.

20. The method according to claim 17, wherein
the semiconductor chips include a controller chip and a plurality of memory chips, and
the controller chip is stacked at the top of the stacked semiconductor chips.
